(19) United States
(12) Patent Application Publication
(10) Pub. No.: US 2005/0258845 A1
(43) Pub. Date: Nov. 24, 2005

(54) PAD TYPE WAFER TEST APPARATUS

(75) Inventors: Wan-Chuan Chou, Chang Hua County (TW); Wei-Fang Fan, Hsinchu County (TW)

Correspondence Address: BACON & THOMAS, PLLC, 625 SLATERS LANE, FOURTH FLOOR, ALEXANDRIA, VA, 22314, US

(73) Assignees: Wan-Chuan Chou, Chang Hua County (TW); Wei-Fang Fan, Hsinchu County (TW); Jen-Pin Su, Hsinchu County (TW)

(21) Appl. No.: 10/981,449

(22) Filed: Nov. 5, 2004

(30) Foreign Application Priority Data
May 20, 2004 (TW) 93114281

(51) Int. Cl. G01R 31/02

(52) U.S. Cl. 324/754

(57) ABSTRACT

Provided is a pad type wafer test apparatus comprises a disk-shaped substrate, a buffer assembly comprising a cross-shaped seat, a body, a buffer pad, and a rectangular frame element, a conductive assembly, and a rectangular test probe mechanism provided between the body and the conductive member and electrically coupled thereto. In a conductivity test for finding any defect in wafer a wafer is placed on a machine, the test probe mechanism is placed on the wafer with test probes of the test probe mechanism being in contact with the wafer by inserting into an oxidized film on the wafer, and test result is transmitted to a display via the test probes and the substrate. The invention can accurately find any wafer defect, protect test probes, and effect a dense configuration of test probes.

### FIELD OF THE INVENTION

The present invention relates to wafer test apparatuses and more particularly to a pad type apparatus for testing a defect in the wafer.

### BACKGROUND OF THE INVENTION

Conventionally, prior to wafer dicing the wafer is required to test for finding any defect. This is because a single defect in a single wafer of silicon can completely ruin the wafer.

A conventional wafer prior to dicing is shown in FIG. 1. As shown, a pad is formed on the wafer. Further, an oxidized film as protection is formed on the pad. Each of a plurality of devices to be formed on the wafer is tested as detailed below. A prior test probe mechanism 90 comprises a plurality of test probes 91 obliquely provided on a substrate 92. One end of the test probe 91 is secured to the substrate 92 by soldering and the other end thereof is secured to the substrate 92 by means of a layer of epoxy 93. The other end of the test probe 91 is bent to form a pointed end 911. The pointed ends 911 insert into the oxidized film for testing conductivity of the wafer.

However, the prior conductivity test with respect to wafer suffered from several disadvantages. For example, the advanced test probes are subject to damage in tip length, alignment, planarity, etc. As a result, test accuracy is low. Further, the cost of repairing the damaged test probes is very high. A pad size is typically at least 70 μm. Also, gap between two adjacent pads is continuously decreasing as manufacturing process advances. Unfortunately, it is very difficult of arranging the prior test probes in a dense configuration. Hence, a need for improvement exists.

### SUMMARY OF THE INVENTION

It is an object of the present invention to provide a wafer test apparatus comprising a disk-shaped substrate comprising a central, rectangular first opening, a plurality of larger first holes, a plurality of smaller second holes, a plurality of first apertures, and a plurality of cavities formed on its bottom wherein the first apertures and the second holes are alternate at each side of the first opening; a buffer assembly comprising a cross-shaped seat, a body, a buffer pad, and a rectangular frame element wherein the seat is secured to the substrate, the body includes a bottom plate, a cylindrical portion partially passed the first opening from below and secured to the seat, a plurality of longitudinal receptacles formed on the cylindrical portion, and a plurality of resilient members anchored in the receptacles and having its upper portions threadably secured to a bottom of the seat, a gap is formed between the body and the seat, the buffer pad and the frame element are provided below the body, the frame element includes a second opening for receiving the buffer pad, and two opposite pins formed on its both ends and adapted to insert into the bottom plate for mounting the frame element in the body, two opposite projected rails are formed on an outer surface of the cylindrical portion, and a sliding member is slidably formed on each rail, the sliding members being secured to the seat; a conductive assembly comprising four separate, rectangular plates, four separate parallelepiped members secured to the substrate by driving a plurality of fasteners through the second holes, each parallelepiped member including a plurality of bottom legs, a plurality of second apertures, and a plurality of pegs, a flat conductive member, and a plurality of conductive, resilient pins wherein the conductive, resilient pins are received in the second apertures, the pegs are inserted into the first apertures for positioning, the conductive member is formed on an underside of the parallelepiped members and includes a plurality of conductors having one ends coupled to one ends of the conductive, resilient pins, and a rectangular third opening, the other ends of the conductive, resilient pins are coupled to the cavities, the conductive member is secured to bottoms of the parallelepiped members, each of the plates includes an inwardly extended staged member, a plurality of third apertures, and a plurality of third holes adjacent the third apertures for receiving the legs for positioning, and the conductive, resilient pins contact the conductors when the conductive member is secured onto the parallelepiped members; and a rectangular test probe mechanism provided between the body and the conductive member, the test probe mechanism being received in both the second and third openings and electrically coupled to the conductive member, the test probe mechanism comprising a plurality of longitudinal test probes on its bottom, wherein in a wafer conductivity test a wafer is placed on a machine, the test probe mechanism is placed on the wafer with the test probes being in contact with the wafer by inserting into an oxidized film on the wafer, and test result is transmitted to a display via the test probes, the conductors, the conductive, resilient pins, and the substrate. By utilizing the present invention, benefits including accurately finding any defect in a wafer, test probes being not subject to wear or damage, and dense configuration of test probes are obtained.

The above and other objects, features and advantages of the present invention will become apparent from the following detailed description taken with the accompanying drawings.

### BRIEF DESCRIPTION OF THE DRAWINGS

FIG. 1 is an exploded view of a conventional test probe mechanism for wafer test;

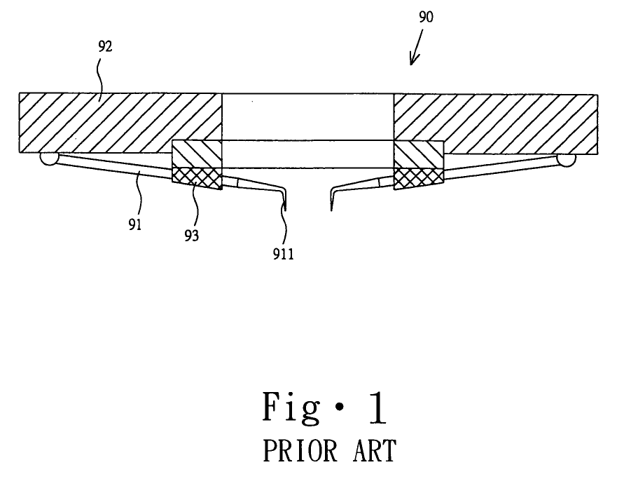

FIG. 2 is a perspective view of a preferred embodiment of wafer test apparatus according to the invention;

FIG. 3 is an exploded view of FIG. 2;

FIG. 4 is a cross-sectional view of FIG. 2;

FIG. 5 is a perspective view of the wafer test apparatus of the invention to be mounted on a machine in a test; and

FIG. 6 is a cross-sectional view showing the wafer test apparatus of the invention in a test position.

### DETAILED DESCRIPTION OF THE PREFERRED EMBODIMENTS

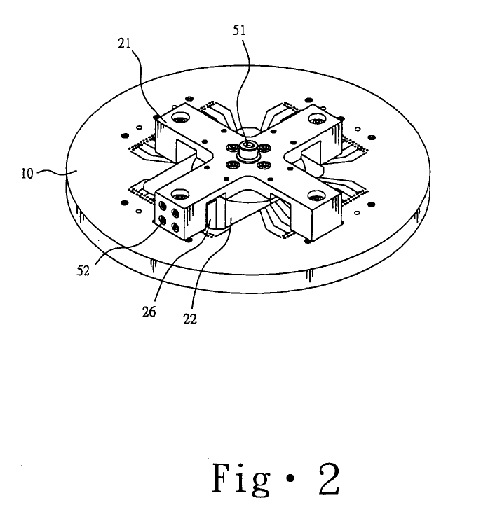

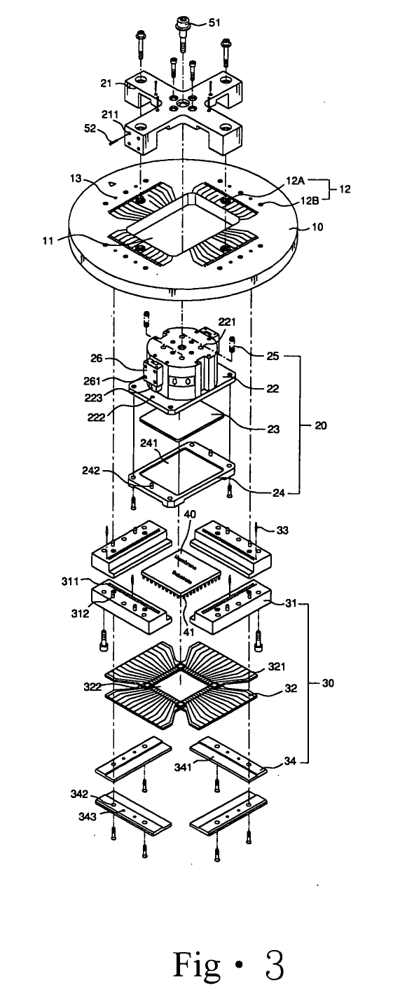

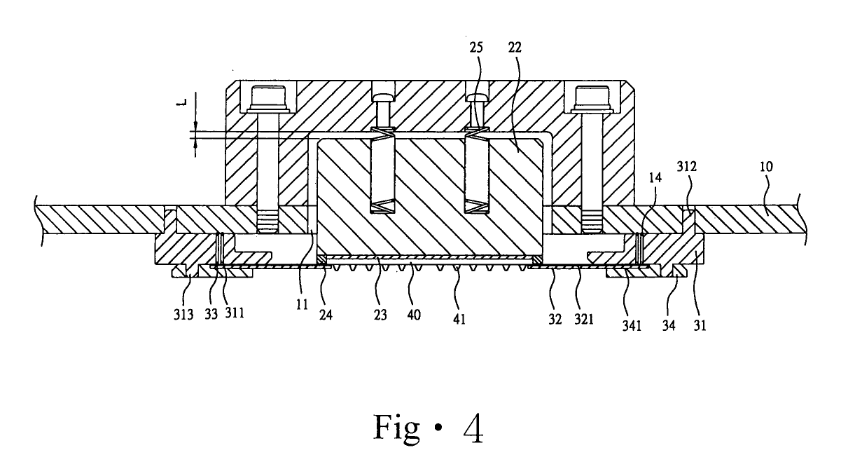

Referring to FIGS. 2 to 6, a wafer test apparatus constructed in accordance with a preferred embodiment of the invention is shown. The apparatus comprises a substrate 10, a buffer assembly 20 mounted on the substrate 10, a conductive assembly 30 mounted under the substrate 10, and a test probe mechanism 40 mounted in the conductive assembly 30. Each component will be described in detailed below.

The substrate 10 is a disk-shaped PCB (printed circuit board) and comprises a central, rectangular opening 11, a plurality of holes 12 including larger first holes 12A and smaller second holes 12B, and a plurality of apertures 13 in which the apertures 13 and the second holes 12B are alternate at each side of the opening 11.

The buffer assembly 20 comprises a cross-shaped seat 21, a body 22, a buffer pad 23, and a rectangular frame element 24. A plurality of screws are driven through the seat 21 into the first holes 12A for fastening the seat 21 on the substrate 10. A cylindrical portion of the body 22 partially passes the opening 11 from below to be secured to the seat 21 by a screw 51. A plurality of longitudinal receptacles 221 are formed on the cylindrical portion of the body 22. A plurality of resilient members 25 are anchored in the receptacles 221 and have its upper portions threadably secured to a bottom of the seat 21 (i.e., the body 22 and the seat 21 are secured together). A gap L as a buffer space is formed between a top of the body 22 and the bottom of the seat 21. The buffer pad 23 and the frame element 24 are provided below the body 22. An opening 241 is formed in the frame element 24 for receiving the buffer pad 23. Two opposite pins 242 are formed on both ends of the frame element 24 and are adapted to insert into holes 222 on a bottom plate of the body 22 for mounting the frame element 24 in the body 22.

Two opposite projected rails 223 are formed on an outer surface of the cylindrical portion of the body 22. A sliding member 26 is slidably formed on the rail 223. A plurality of threaded holes 261 are formed on the sliding member 26. A plurality of screws 52 are adapted to drive through a plurality of apertures 211 on either one of two opposite members of the seat 21 into the holes 261 for fastening the seat 21 and the body 22 together.

The conductive assembly 30 comprises four separate parallelepiped members 31 each threadably secured to the second holes 12B by driving a plurality of screws therethrough, and a conductive member 32. A row of plurality of apertures 311 are formed on each parallelepiped member 31 for receiving a plurality of conductive, resilient pins 33. Note that two rows of plurality of apertures 311 may be formed on each parallelepiped member 31 in other embodiments for accommodating the increased number of test probes 41 of the test probe mechanism 40. Also, a plurality of pegs 312 are formed on each parallelepiped member 31 and are adapted to insert into the apertures 13 for positioning when each parallelepiped member 31 is threadably secured to the second holes 12B by driving a plurality of screws therethrough.

The flat conductive member 32 is formed on an underside of the parallelepiped members 31. A plurality of conductors 321 are formed on the conductive member 32 and a rectangular opening 322 are formed in the conductive member 32. The opening 322 has an area slightly smaller than that of the test probe mechanism 40. One ends of the conductors 321 are coupled to one ends of the pins 33. The other ends of the pins 33 are coupled to the bottom of the substrate 10. A plurality of cavities 14 are formed on the bottom of the substrate 10 for reliably receiving tops of the pins 33.

The conductive member 32 is secured to bottoms of the parallelepiped members 31 by diving a plurality of screws through apertures 342 of four separate, rectangular plates 34 into the parallelepiped members 31. The plate 34 comprises an inwardly extended staged member 341 besides the apertures 342. A plurality of holes 343 are formed adjacent the apertures 342 for receiving a plurality of legs 313 on bottom of each parallelepiped member 31 for positioning. As an end, ends of the pins 33 may contact the conductors 321 accurately when the conductive member 32 is secured onto the parallelepiped members 31. Note that both the parallelepiped members 31 and the plates 34 may be formed integrally in other embodiments.

The rectangular test probe mechanism 40 is adapted to contact a wafer to be tested and is provided between the body 22 and the conductive member 32. The test probe mechanism 40 is received in the opening 241 for positioning. Also, the test probe mechanism 40 is received in the opening 322 and is electrically coupled to the conductive member 32. The test probe mechanism 40 comprises a plurality of longitudinal test probes 41 on its bottom. The test probe 41 has low impedance and is not subject to wear or deflection when contacting the wafer. Further, the test probes 41 can be arranged in a dense configuration.

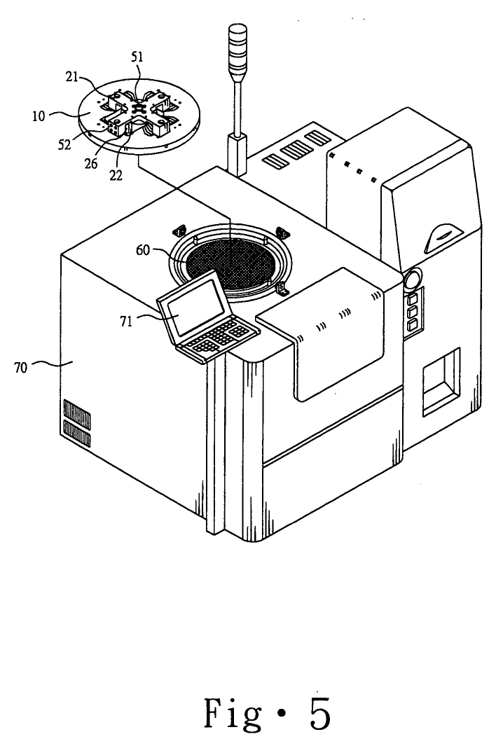

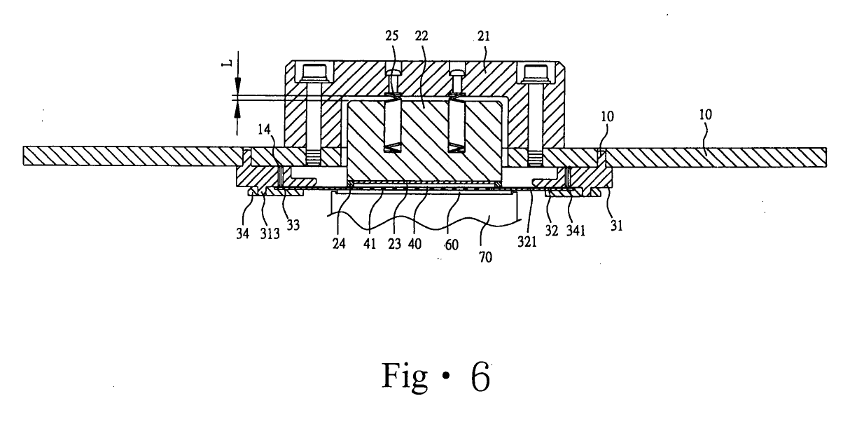

Referring to FIGS. 5 and 6 specifically, a process of testing conductivity of wafer comprises placing a wafer 60 on a machine 70, and placing a test probe mechanism 40 on the wafer 60 with a plurality of test probes 41 of the test probe mechanism 40 being in contact with the wafer 60 for conductivity test. Data with respect to conductivity of the wafer 60 is transmitted to a display 71 provided on the machine 70 via the test probes 40, the conductors 321, the pins 33, and the substrate 10. The test probes 41 are adapted to insert into the oxidized film formed on the wafer 60 in the test. Fortunately, the provisions of gap L and sliding members 26 can effect an accurate contact of the test probes 41 with the wafer 60 in a resilient manner.

The benefits of the invention include accurately finding any defect in a wafer, test probes being not subject to wear or damage, and dense configuration of test probes.

While the invention herein disclosed has been described by means of specific embodiments, numerous modifications and variations could be made thereto by those skilled in the art without departing from the scope and spirit of the invention set forth in the claims.

1. A wafer test apparatus comprising:
a disk-shaped substrate comprising a central, rectangular first opening, a plurality of larger first holes, a plurality of smaller second holes, a plurality of first apertures, and a plurality of cavities formed on its bottom wherein the first apertures and the second holes are alternate at each side of the first opening;
a buffer assembly comprising a cross-shaped seat, a body, a buffer pad, and a rectangular frame element wherein the seat is secured to the substrate, the body includes a bottom plate, a cylindrical portion partially passed the first opening from below and secured to the seat, a plurality of longitudinal receptacles formed on the cylindrical portion, and a plurality of resilient members anchored in the receptacles and having its upper portions threadably secured to a bottom of the seat, a gap is formed between the body and the seat, the buffer pad and the frame element are provided below the body, the frame element includes a second opening for receiving the buffer pad, and two opposite pins formed on its both ends and adapted to insert into the bottom plate for mounting the frame element in the body, two opposite projected rails are formed on an outer surface of the cylindrical portion, and a sliding member is slidably formed on each rail, the sliding members being secured to the seat;
a conductive assembly comprising four separate, rectangular plates, four separate parallelepiped members secured to the substrate by driving a plurality of fasteners through the second holes, each parallelepiped member including a plurality of bottom legs, a plurality of second apertures, and a plurality of pegs, a flat conductive member, and a plurality of conductive, resilient pins wherein the conductive, resilient pins are received in the second apertures, the pegs are inserted into the first apertures for positioning, the conductive member is formed on an underside of the parallelepiped members and includes a plurality of conductors having one ends coupled to one ends of the conductive, resilient pins, and a rectangular third opening, the other ends of the conductive, resilient pins are coupled to the cavities, the conductive member is secured to bottoms of the parallelepiped members, each of the plates includes an inwardly extended staged member, a plurality of third apertures, and a plurality of third holes adjacent the third apertures for receiving the legs for positioning, and the conductive, resilient pins contact the conductors when the conductive member is secured onto the parallelepiped members; and
a rectangular test probe mechanism provided between the body and the conductive member, the test probe mechanism being received in both the second and third openings and electrically coupled to the conductive member, the test probe mechanism comprising a plurality of longitudinal test probes on its bottom,
wherein in a wafer conductivity test a wafer is placed on a machine, the test probe mechanism is placed on the wafer with the test probes being in contact with the wafer by inserting into an oxidized film on the wafer, and test result is transmitted to a display via the test probes, the conductors, the conductive, resilient pins, and the substrate.
